(19) United States
(12) Patent Application Publication
(10) Pub. No.: US 2022/0123193 A1
(43) Pub. Date: Apr. 21, 2022

(54) (RE,Y)-123 SUPERCONDUCTING FILM CONTAINING MIXED ARTIFICIAL PINNING CENTERS AND PREPARATION METHOD THEREOF

(71) Applicant: Shanghai Superconductor Technology Co., Ltd., Shanghai City (CN)

(72) Inventors: Yue ZHAO, Shanghai City (CN); Yue WU, Shanghai City (CN); Guangyu JIANG, Shanghai City (CN); Jiamin ZHU, Shanghai City (CN); Donghong WU, Shanghai City (CN); Yu CHEN, Shanghai City (CN); Yijun DING, Shanghai City (CN)

(21) Appl. No.: 16/950,435

(22) Filed: Nov. 17, 2020

(30) Foreign Application Priority Data
Oct. 19, 2020 (CN) 2020111207519

(51) Int. Cl. H01L 39/12; H01L 39/24; C23C 14/08; C23C 14/28

(52) U.S. Cl. CPC H01L 39/126; H01L 39/2448; C23C 14/28; C23C 14/08; H01L 39/2461

(57) ABSTRACT

The invention relates to a (RE,Y)-123 superconducting film containing mixed artificial pinning centers and a preparation method thereof, wherein a stoichiometric ratio of Cu in a parent phase of the (RE,Y)-123 superconducting film is 3.05-5; the mixed artificial pinning centers include a perovskite structure BaMO3 and a double-perovskite structure oxide Ba2(RE,Y)NO6; and a total mole percentage of Ba2(RE,Y)NO6 in the superconducting film is not less than 2.5%. The mixed artificial pinning centers form well-aligned column structures along the thickness direction in the superconducting film. The invention is intended not only to solve the problem that a single secondary phase cannot be well aligned along the thickness direction of (RE,Y)-123 when using the high-speed pulsed laser deposition technique, but also to effectively overcome the film thickness effect of the (RE,Y)-123 superconducting film containing mixed artificial pinning centers, hence the in-field current carrying capacity of the superconducting film is significantly improved in industrialized high-speed production.

### FIELD OF THE INVENTION

The invention relates to the technical field of preparation of superconductors, in particular to a (RE,Y)-123 superconducting film containing mixed artificial pinning centers and a preparation method thereof, and more particularly, to a process suitable for producing a second-generation high-temperature superconducting tape containing mixed artificial pinning centers, which can obtain artificial pinning centers having highly ordered column structures along the thickness direction under a high-speed deposition condition, and can remarkably improve the in-field current carrying capacity of the superconducting tape.

### BACKGROUND OF THE INVENTION

As a practical superconductor with promising application prospect, the second-generation high-temperature superconducting tape has a (RE,Y)—Ba—Cu—O copper oxide compound (abbreviated as (RE,Y)-123 hereinafter) as its core functional layer. Compared with other practical superconductors, the copper oxide compound has the advantages of high superconducting transition temperature, high current carrying capacity, high irreversibility field and the like. A “coated conductor” (i.e., a second-generation high-temperature superconducting tape, hereinafter referred to as the second-generation tape) can be obtained by depositing this material on a flexible substrate in a thin film epitaxial manner. The second-generation tape features high critical engineering current, excellent mechanical properties in a high-temperature region, especially in an applied magnetic field; moreover, the second-generation tape requires low costs in raw materials and thus has potential advantages in price. Such a material is expected to serve as a basic material support in the future, and to promote the development of practical superconducting technologies such as special medical treatment in high magnetic field, large-scale scientific equipment, and compact fusion.

Enormous research into the application in strong magnetic field has focused on improving the current carrying capacity of the second-generation high-temperature superconducting tape in a low-temperature region and an applied magnetic field (i.e., the maximum current value carried under the condition of an applied magnetic field, usually the applied magnetic field can be a low-mid magnetic field regime, for example, 0-5 T, and a high magnetic field regime, for example, above 10 T). A common solution is to introduce a secondary phase, namely, the “artificial pinning center”, into the superconducting film (Superconductor Science and Technology 30.12 (2017): 123001). Research in this regard began in 2004 (Nature materials 3.7 (2004): 439), and after nearly two decades of development, many scholars have studied the types of the secondary phase (US20190318849A1, US20160172080A1, US20110287939A1, US20110034336A1), but the secondary phases in them are all generated at a low growth rate (<1 nm/s), and the secondary phase materials employed are all singular. The in-field current carrying density of the second-generation superconducting tape has increased to fifty times the level in 2010 (Superconductor Science and Technology 31.10 (2018): 10LT01), the performance of the tape has reached five times that of the low-temperature superconductor Nb3 Sn, marking the beginning of a new era of the application of the second-generation superconducting tape in the high-field magnet. The major object of introducing artificial pinning centers is to form well-aligned column structures along the thickness direction, which requires slow growth, typically at growth rates below 5 to 7 nm/s (IEEE Transactions on Applied Superconductivity 28.4 (2018): 6600604). If the growth rate is higher than 10 nm/s or more, the well-aligned column structures along the thickness direction are destroyed, and the secondary phase forms nano-dots, inclined nano-rods, or a mixed landscape of both (2017 Jpn. J. Appl. Phys. 56 015601), which renders a significant inferiority in the current carrying capacity of the superconducting film to those having the column structures. This limitation in growth rate results in a lower yield of high-performance tapes, failing to meet the requirements of large-scale applications.

### SUMMARY OF THE INVENTION

It's an object of the present invention to address the limitation of the growth rate in the prior art by providing a (RE,Y)-123 (i.e., an abbreviation of (RE,Y)Ba₂Cu₃₊ₓO₇, (RE,Y) representing RE and/or Y) superconducting film containing mixed artificial pinning centers and a preparation method thereof, so that a secondary phase having well-aligned column structures along the thickness direction can still be obtained under high-growth-rate production conditions (growth rate higher than 20 nm/s).

The object of the invention is realized through the following technical solution.

The invention provides a (RE,Y)-123 superconducting film containing mixed artificial pinning centers, wherein a stoichiometric ratio of Cu in a parent phase of the (RE,Y)-123 superconducting film is 3.05 to 5, that is, in (RE,Y)Ba₂Cu₃₊ₓO₇, a value of x is 0.05 to 2;

the mixed artificial pinning centers comprise a perovskite structure BaMO₃ and a double-perovskite structure oxide Ba₂(RE,Y)NO₆;

a total mole percentage of the double-perovskite structure oxide Ba₂(RE,Y)NO₆ in the superconducting film is not less than 2.5%;

the mixed artificial pinning centers form well-aligned column structures along the thickness direction in the superconducting film.

Preferably, in the (RE,Y)-123 superconducting film, RE is a mixed rare earth consisting of one or more selected from Gd, Eu, and Sm.

Preferably, in the perovskite structure BaMO₃, M is a mixed element consisting of one or more selected from Zr, Hf, and Sn; in the double-perovskite structure oxide Ba₂(RE,Y)NO₆, RE is a mixed rare earth consisting of one or more selected from Gd, Eu, and Sm, and N is a mixed element consisting of one or more selected from Nb and Ta.

Preferably, a total mole percentage of the mixed artificial pinning centers in the superconducting film is 5-20%.

The present invention further provides a method for preparing the (RE,Y)-123 superconducting film containing mixed artificial pinning centers, including the steps of: S1, preparing a (RE,Y)-123 superconducting target containing mixed artificial pinning centers; S2, selecting a buffered metallic tape with biaxial texture as a substrate; and S3, depositing the target in step S1 on the substrate in step S2 in situ by adopting a high-speed pulsed laser deposition technique to obtain the (RE,Y)-123 superconducting film containing mixed artificial pinning centers.

Preferably, in step S1, the target is a conformable metal oxide target and prepared by uniformly mixing secondary phase BaMO₃ and Ba₂(RE,Y)NO₆ powder and parent phase (RE,Y)-123 superconducting powder, pressing and sintering, and obtaining the (RE,Y)-123 superconducting target containing mixed artificial pinning centers after surface treatment.

Preferably, a density of the target reaches more than 90% of a theoretical density.

Preferably, in step S2, the metallic tape is a nickel-based or copper-based flexible metallic tape, the metallic tape is coated with a single-layer or multi-layers of oxide films, and a structure of the oxide film is one of CeO₂/YSZ/Y₂O₃, MgO, LaMnO₃/MgO/Y₂O₃/Al—O or CeO₂/MgO/Y₂O₃/Al—O.

Preferably, in step S3, the superconducting film prepared by in-situ deposition grows at a growth rate higher than 20 nm/s.

More preferably, the superconducting film prepared by in-situ deposition grows at a growth rate of 20-50 nm/s.

Preferably, in step S3, the superconducting film prepared by in-situ deposition has a thickness of more than 1 μm, and field current carrying capacity is significantly improved compared with that of a superconducting film prepared not by the method of the present invention.

Compared with the prior art, the invention has the following advantages.

1. According to the invention, the secondary phase perovskite and double-perovskite structures are mixed, and the stoichiometric ratio of Cu in the superconducting parent phase (RE,Y)-123 is increased, so that under the growth condition of high-speed pulsed laser deposition (at a growth rate higher than 20 nm/s), the secondary phase having well-aligned column structures along the thickness direction can still be obtained in the (RE,Y)-123 superconducting film.
2. The method of the present invention not only solves the problem that a single secondary phase cannot be well aligned along the thickness direction of (RE,Y)BCO when using the high-speed pulsed laser deposition technique, but also effectively overcomes the film thickness effect of the (RE,Y)-123 superconducting film containing mixed artificial pinning centers, and can prepare the superconducting film with a thickness of more than 1 μm.
3. The in-field current carrying capacity of the superconducting film prepared by the method of the present invention is obviously improved, so that the production efficiency of the high-performance superconducting tape significantly increases, and the productivity of single pulsed laser deposition equipment is higher.

### BRIEF DESCRIPTION OF THE DRAWINGS

Other features, objects, and advantages of the present invention will become apparent from the following detailed description of non-limiting embodiments in conjunction with the accompanying drawings, in which:

FIG. 1 is a 2D X-ray diffraction pattern of a superconducting film prepared in Example 1;

FIG. 2 is a cross-sectional transmission electron microscopic (TEM) image of the superconducting film prepared in Example 1;

FIG. 3 is a cross-sectional TEM image of the superconducting film prepared in Comparative Example 1.

### DETAILED DESCRIPTION OF THE INVENTION

The present invention will now be described in detail with reference to specific examples. The following examples will help those skilled in the art to further understand the invention, but are not intended to limit the invention in any way. It should be noted that several variations and modifications may be made by those skilled in the art without departing from the inventive concept. The variations and modifications are within the scope of the invention.

Mole percentages of the perovskite structure BaMO₃ and the double-perovskite structure oxide Ba₂(RE,Y)NO₆ described in the following examples refer to the mole percentages thereof in the superconducting film.

### Example 1

This Example related to a Gd—Ba—Cu—O (Gd-123) superconducting film containing mixed artificial pinning centers, wherein the mixed artificial pinning centers included a perovskite structure BaZrO₃ and a double-perovskite structure oxide Ba₂YNbO₆, the mole percentage of BaZrO₃ was 2%, the mole percentage of Ba₂YNbO₆ was 3%, and a stoichiometric ratio of Cu in a parent phase (RE,Y)-123 superconducting film was 3.05; the preparation method of the Gd—Ba—Cu—O (Gd-123) superconducting film containing mixed artificial pinning centers included the steps of:

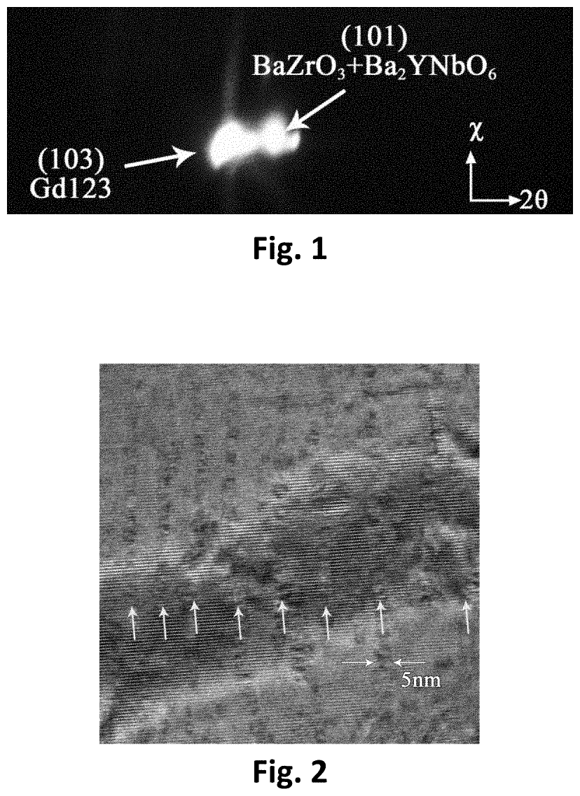

(1) preparing a Gd-123 superconducting target containing two mixed artificial pinning centers: uniformly mixing 2% by mole of BaZrO₃ and 3% by mole of Ba₂YNbO₆ powder with parent phase Gd-123 superconducting powder, pressing and sintering, and obtaining the Gd-123 superconducting target containing two mixed artificial pinning centers through surface treatment, wherein a density of the target reaches 90% of a theoretical density.
(2) selecting a metallic tape with a biaxially textured CeO₂/MgO/Y₂O₃/Al—O buffer layer as a substrate; and
(3) depositing the target in step (1) on the substrate in step (2) in situ by adopting a high-speed pulsed laser deposition technique, at a growth rate of 20 nm/s, and obtaining the Gd-123 superconducting film containing mixed artificial pinning centers after deposition.
The superconducting film prepared by the method of Example 1 had a thickness of 2 μm, and the mixed artificial pinning centers BaZrO₃ and Ba₂YNbO₆ could still achieve well-aligned column structures along the thickness direction in the superconducting film. The 2D X-ray diffraction pattern of the superconducting film was shown in FIG. 1, and the diffraction peaks of (101) crystal planes of BaZrO₃ and Ba₂YNbO₆ indicated by arrows in the drawing showed that the mixed artificial pinning centers formed column structures along the thickness direction. A cross-sectional TEM image of the superconducting film was shown in FIG. 2, arrows indicated the distribution of columnar crystals with a column structure diameter of about 5 nm, and the superconducting film had an in-field current carrying density of 15 MA/cm² at 30 K in 1 T field (B//the thickness di recti on).

### Example 2

This Example related to a (Gd,Sm)—Ba—Cu—O (denoted as (Gd,Sm)-123) superconducting film containing mixed artificial pinning centers, wherein the mixed artificial pinning centers included a perovskite structure BaHfO₃ and a double-perovskite structure oxide Ba₂GdNbO₆, the mole percentage of BaHfO₃ was 4%, the mole percentage of Ba₂GdNbO₆ was 2.5%, and a stoichiometric ratio of Cu in a parent phase (RE,Y)-123 superconducting film was 3.5; the preparation method of the (Gd,Sm)-123 superconducting film containing mixed artificial pinning centers included the steps of:

(1) preparing a (Gd,Sm)-123 superconducting target containing two mixed artificial pinning centers: uniformly mixing 4% by mole of BaHfO₃ and 2.5% by mole of Ba₂GdNbO₆ powder with parent phase (Gd,Sm)-123 superconducting powder, pressing and sintering, and obtaining the (Gd,Sm)-123 superconducting target containing two mixed artificial pinning centers through surface treatment, wherein a density of the target reaches 95% of a theoretical density.
(2) selecting a metallic tape with a biaxially textured MgO buffer layer as a substrate; and
(3) depositing the target in step (1) on the substrate in step (2) in situ by adopting a high-speed pulsed laser deposition technique, at a growth rate of 50 nm/s, and obtaining the (Gd,Sm)-123 superconducting film containing mixed artificial pinning centers after deposition.
The superconducting film prepared by the method of Example 2 had a thickness of 1 and the mixed artificial pinning centers BaZrO₃ and Ba₂YNbO₆ could still achieve well-aligned column structures along the thickness direction in the superconducting film and the superconducting film had an in-field current carrying density of 13 MA/cm² at 30 K in 1 T field (B//the thickness di recti on).

### Example 3

This Example related to a Y—Ba—Cu—O (denoted as Y-123) superconducting film containing mixed artificial pinning centers, wherein the mixed artificial pinning centers included a perovskite structure BaSnO₃ and a double-perovskite structure oxide Ba₂GdTaO₆, the mole percentage of BaSnO₃ was 6%, the mole percentage of Ba₂GdTaO₆ was 6%, and a stoichiometric ratio of Cu in a parent phase (RE,Y)-123 superconducting film was 4; the preparation method of the Y-123 superconducting film containing mixed artificial pinning centers included the steps of:

(1) preparing a Y-123 superconducting target containing two mixed artificial pinning centers: uniformly mixing 6% by mole of BaSnO₃ and 6% by mole of Ba₂GdTaO₆ powder with parent phase Y-123 superconducting powder, pressing and sintering, and obtaining the Y-123 superconducting target containing two mixed artificial pinning centers through surface treatment, wherein a density of the target reaches 92% of a theoretical density.
(2) selecting a metallic tape with a biaxially textured LaMnO₃/MgO/Y₂O₃/Al—O buffer layer as a substrate; and
(3) depositing the target in step (1) on the substrate in step (2) in situ by adopting a high-speed pulsed laser deposition technique, at a growth rate of 25 nm/s, and obtaining the Y-123 superconducting film containing mixed artificial pinning centers after deposition.
The superconducting film prepared by the method of Example 2 had a thickness of 2.5 and the mixed artificial pinning centers BaSnO₃ and Ba₂YTaO₆ could still achieve well-aligned column structures along the thickness direction in the superconducting film and the superconducting film had an in-field current carrying density of 16 MA/cm² at 4.2 K in 10 T field (B//the thickness di recti on).

### Example 4

This Example related to a (Eu,Gd)—Ba—Cu—O (denoted as (Eu,Gd)-123) superconducting film containing mixed artificial pinning centers, wherein the mixed artificial pinning centers included two perovskite structure BaZrO₃ and BaSnO₃ and two double-perovskite structure oxide Ba₂YTaO₆ and Ba₂YNbO₆, the mole percentage of BaSnO₃, BaZrO₃, Ba₂YTaO₆ and Ba₂YNbO₆ were 7%, 8%, 2.5% and 2.5%, respectively. The stoichiometric ratio of Cu in a parent phase (RE,Y)-123 superconducting film was 5; the preparation method of the (Eu,Gd)-123 superconducting film containing mixed artificial pinning centers included the steps of:

(1) preparing a (Eu,Gd)-123 superconducting target containing two mixed artificial pinning centers: uniformly mixing 7% by mole of BaSnO₃, 8% by mole of BaZrO₃, 2.5% by mole of Ba₂YTaO₆ and 2.5% by mole of Ba₂YNbO₆ powder with parent phase (Eu,Gd)-123 superconducting powder, pressing and sintering, and obtaining the (Eu,Gd)-123 superconducting target containing two mixed artificial pinning centers through surface treatment, wherein a density of the target reaches 97% of a theoretical density.
(2) selecting a metallic tape with a biaxially textured LaMnO₃/MgO/Y₂O₃/Al—O buffer layer as a substrate; and
(3) depositing the target in step (1) on the substrate in step (2) in situ by adopting a high-speed pulsed laser deposition technique, at a growth rate of 25 nm/s, and obtaining the (Eu,Gd)-123 superconducting film containing mixed artificial pinning centers after deposition.

The superconducting film prepared by the method of Example 2 had a thickness of 2.5 μm, and the mixed artificial pinning centers BaSnO₃, BaZrO₃, Ba₂YNbO₆ and Ba₂YTaO₆ could still achieve well-aligned column structures along the thickness direction in the superconducting film and the superconducting film had an in-field current carrying density of 20 MA/cm² at 4.2 K in 10 T field (B//the thickness direction).

### Comparative Example 1

This Comparative Example related to a Gd—Ba—Cu—O superconducting film containing mixed artificial pinning centers, the method being substantially the same as in Example 1, except that in this Comparative Example, the mixed artificial pinning centers were BaZrO₃ and Y₂O₃ with mole percentages of 2% and 3%, respectively.

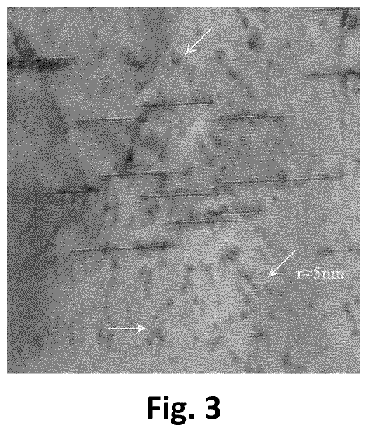

The structures of the obtained superconducting film artificial pinning centers BaZrO₃ and Y₂O₃ in the superconducting film were nano-dots, and could not achieve well-aligned column structures at a high growth rate. A cross-sectional TEM image of the superconducting film was shown in FIG. 3, it could be seen that the superconducting film had only nano-dots formed therein (with a diameter of 5 nm), without apparent column structures. The superconducting film had an in-field current carrying density of 2 MA/cm² at 30 K in 1 T field (B//the thickness direction).

### Comparative Example 2

This Comparative Example related to a Gd—Ba—Cu—O superconducting film containing mixed artificial pinning centers, the method being substantially the same as in Example 1, except that in this Comparative Example, the mixed artificial pinning centers only was BaZrO₃ with mole percentages of 5%.

The structures of the obtained superconducting film artificial pinning centers BaZrO₃ in the superconducting film was nano-dots, and could not achieve well-aligned column structures at a high growth rate. The superconducting film had an in-field current carrying density of 1.5 MA/cm^{2 at} 30 K in 1 T field (B//the thickness direction).

### Comparative Example 3

This Comparative Example related to a (Gd, Sm)—Ba—Cu—O superconducting film containing mixed artificial pinning centers, the method being substantially the same as in Example 2, except that in this Comparative Example, the stoichiometric ratio of Cu in a parent phase (Gd, Sm)—Ba—Cu—O superconducting film was 3.

The structures of the obtained superconducting film artificial pinning centers of BaHfO₃ and Ba₂GdNbO₆ in the superconducting film were a mixture of nano-dots and column. The superconducting film had an in-field current carrying density of 4 MA/cm² at 30 K in 1 T field (B//the thickness direction).

### Comparative Example 4

This Comparative Example related to a Y—Ba—Cu—O superconducting film containing mixed artificial pinning centers, the method being substantially the same as in Example 3, except that in this Comparative Example, the mole percentages of Ba₂GdTaO₆ was 2%.

The structures of the obtained superconducting film artificial pinning centers of Ba₂GdTaO₆ in the superconducting film were a mixture of nano-dots and column. The superconducting film had an in-field current carrying density of 4 MA/cm² at 4.2 K in 10 T field (B//the thickness direction).

Specific examples of the invention have been described above. It is to be understood that the invention is not limited to the particular examples described above, and that various changes and modifications may be made by one skilled in the art with the scope of the appended claims without departing from the spirit of the invention. Without conflicts, the examples of the present application and features of the examples may be combined randomly.

1. A (RE,Y)-123 superconducting film containing mixed artificial pinning centers, wherein
a stoichiometric ratio of Cu in a parent phase of the (RE,Y)-123 superconducting film is 3.05 to 5;
the mixed artificial pinning centers comprise a perovskite structure BaMO₃ and a double-perovskite structure oxide Ba₂(RE,Y)NO₆;
a total mole percentage of the double-perovskite structures oxide Ba₂(RE,Y)NO₆ in the superconducting film is not less than 2.5%;
the mixed artificial pinning centers form well-aligned column structures along the thickness direction in the superconducting film.

2. The (RE,Y)-123 superconducting film containing mixed artificial pinning centers according to claim 1, wherein in the (RE,Y)-123 superconducting film, RE is a mixed rare earth consisting of one or more selected from Gd, Eu, and Sm.

3. The (RE,Y)-123 superconducting film containing mixed artificial pinning centers according to claim 1, wherein in the perovskite structure BaMO₃, M is a mixed element consisting of one or more selected from Zr, Hf, and Sn; in the double-perovskite structure oxide Ba₂(RE,Y)NO₆, RE is a mixed rare earth consisting of one or more selected from Gd, Eu, and Sm, and N is a mixed element consisting of one or more selected from Nb and Ta.

4. The (RE,Y)-123 superconducting film containing mixed artificial pinning centers according to claim 1, wherein a total mole percentage of the mixed artificial pinning centers in the superconducting film is 5-20%.

5. A method for preparing the (RE,Y)-123 superconducting film containing mixed artificial pinning centers according to claim 1, comprising the steps of:
S1, preparing a (RE,Y)-123 superconducting target containing mixed artificial pinning centers;

6. S2, selecting a buffered metallic tape with biaxial texture as a substrate; and
S3, depositing the target in step S1 on the substrate in step S2 in situ by adopting a high-speed pulsed laser deposition technique to obtain the (RE,Y)-123 superconducting film containing mixed artificial pinning centers.

7. The method for preparing the (RE,Y)-123 superconducting film containing mixed artificial pinning centers according to claim 5, wherein in step S1, the target is a conformable metal oxide target and prepared by uniformly mixing the secondary phase BaMO₃ and Ba₂(RE,Y)NO₆ powder and parent phase (RE,Y)-123 superconducting powder, pressing and sintering, and obtaining the (RE,Y)-123 superconducting target containing mixed artificial pinning centers after surface treatment.

8. The method for preparing the (RE,Y)-123 superconducting film containing mixed artificial pinning centers according to claim 5, wherein a density of the target reaches more than 90% of a theoretical density.

9. The method for preparing the (RE,Y)-123 superconducting film containing mixed artificial pinning centers according to claim 5, wherein in step S2, the metallic tape is a nickel-based or copper-based flexible metallic tape, the metallic tape is coated with a single-layer or multi-layers of oxide films, and s structure of the oxide film is one of CeO₂/YSZ/Y₂O₃, MgO, LaMnO₃/MgO/Y₂O₃/Al—O or CeO₂/MgO/Y₂O₃/Al—O.

10. The method for preparing the (RE,Y)-123 superconducting film containing mixed artificial pinning centers according to claim 5, wherein in step S3, the superconducting film prepared by in-situ deposition grows at a growth rate higher than 20 nm/s. The method for preparing the (RE,Y)-123 superconducting film containing mixed artificial pinning centers according to claim 5, wherein in step S3, the superconducting film prepared by in-situ deposition has a thickness of more than 1 μm.
